(19) United States
(12) Patent Application Publication
(10) Pub. No.: US 2025/0248276 A1
(43) Pub. Date: Jul. 31, 2025

(54) PROTECTION LAYER FOR OLED SUB-PIXELS

(71) Applicant: Applied Materials, Inc., Santa Clara, CA (US)

(72) Inventors: Jungmin LEE, Santa Clara, CA (US); Dieter HAAS, Santa Clara, CA (US); Gregory Max MCDANIEL, San Jose, CA (US); Yu-Hsin LIN, Zhubei City (TW)

(21) Appl. No.: 18/989,192

(22) Filed: Dec. 20, 2024

Related U.S. Application Data
(60) Provisional application No. 63/626,885, filed on Jan. 30, 2024.

(51) Int. Cl. H10K 59/80; H10K 59/12; H10K 59/122; H10K 102/00

(52) U.S. Cl. CPC H10K 59/873; H10K 59/1201; H10K 59/122; H10K 2102/351

(57) ABSTRACT

Embodiments described herein relate to a sub-pixel. In one or more embodiments, a sub-pixel includes a substrate and overhang structures. The overhang structures include an extension disposed past a sidewall of the overhang structures. The sub-pixel further includes an anode disposed over the substrate, an inorganic layer disposed under each extension of the overhang structures, and organic light-emitting diode (OLED) material disposed over the anode. The OLED material is disposed between the inorganic layer under each extension of the overhang structures; The sub-pixel further includes a cathode disposed over the OLED material.

### PRIORITY CLAIM

This application claims priority to U.S. Provisional Patent Application Ser. No. 63/626,885 filed on Jan. 30, 2024 the contents of which are incorporated herein by reference in their entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

Therefore, a need exists for sub-pixel circuits and methods of forming sub-pixel circuits.

### SUMMARY

Embodiments of the present disclosure relate to sub-pixel circuits, OLED sub-pixels, and related components and methods for manufacturing OLED sub-pixels.

In one or more embodiments, a sub-pixel includes a substrate and overhang structures. The overhang structures include an extension disposed past a sidewall of the overhang structures. The sub-pixel further includes an anode disposed over the substrate, an inorganic layer disposed under each extension of the overhang structures, and organic light-emitting diode (OLED) material disposed over the anode. The OLED material is disposed between the inorganic layer under each extension of the overhang structures; The sub-pixel further includes a cathode disposed over the OLED material.

In one or more embodiments, a sub-pixel includes overhang structures disposed over a substrate including an extension disposed past a sidewall of the overhang structures. The sub-pixel further includes an anode disposed over the substrate and an inorganic layer disposed under each extension of the overhang structures. The sub-pixel is made by a process including depositing an organic light-emitting diode (OLED) material over the substrate. The OLED is disposed over the anode. The inorganic layer under each extension of the overhang structures is disposed between the OLED material. The process further includes depositing a cathode, wherein the cathode is disposed under each extension of the overhang structures.

In one or more embodiments a method includes depositing an inorganic layer over a substrate and removing portions of an inorganic layer, such that the inorganic layer is to be disposed under an extension of an overhang structure. The method further includes forming the overhang structures. The overhang structures include the extension disposed past a sidewall of the overhang structures. The method further includes depositing an organic light-emitting diode (OLED) material over the substrate. The OLED is disposed over an anode. The inorganic layer under each extension of the overhang structures is disposed between the OLED material. The method further includes depositing a cathode, wherein the cathode is disposed under each extension of the overhang structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit according to embodiments.

FIG. 1B is a schematic, cross-sectional view of a sub-pixel circuit according to one or more embodiments.

FIGS. 2A-2C are schematic, schematic, cross-sectional view of an overhang structure of the sub-pixel circuit of FIG. 1A according to one or more embodiments.

FIG. 3 is a schematic, top view of either sub-pixel circuit from FIG. 1A or FIG. 1B having a line-type architecture according to one or more embodiments.

FIG. 4 is a flow diagram of a method for forming a sub-pixel circuit according to one or more embodiments.

FIG. 5A-5G are schematic, cross-sectional views of a substrate during a method of FIG. 4 for forming a sub-pixel circuit according to one or more embodiments.

FIG. 6 is a flow diagram of a method for forming a sub-pixel according to according to one or more embodiments.

FIGS. 7A-7J are schematic, cross-sectional views of a substrate during the method of FIG. 6 for forming a sub-pixel circuit according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced overhang structures to improve functionality of the display.

In one embodiment, a sub-pixel is provided. The sub-pixel includes an anode, overhang structures, an inorganic layer, an organic light emitting diode (OLED) material, and a cathode. The anode is defined by adjacent first overhang structure and adjacent second overhang structure. The overhang structures are disposed over the inorganic layer. The overhang structures include a second structure disposed over the first structure. A bottom surface of the second structure extends laterally past an upper surface of the first structure The OLED material is disposed over the anode and an upper surface of the inorganic layer. The cathode disposed over the OLED material and an upper surface of the inorganic layer under the extensions of the second structures of the adjacent overhang structures. In one or more embodiments a pixel-isolation structure (PIS) is deposited below the adjacent overhang structures. In one or more embodiments the PIS is deposited below inorganic layer. In one or more embodiments the PIS is deposited over an upper surface of the inorganic layer.

Each of the embodiments described herein of the sub-pixel circuit include a plurality of sub-pixels with each of the sub-pixels are defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more subpixels. Each sub-pixel has OLED materials configured to emit a white, red, green, blue or other color light when energized. E.g., the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles, i.e., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

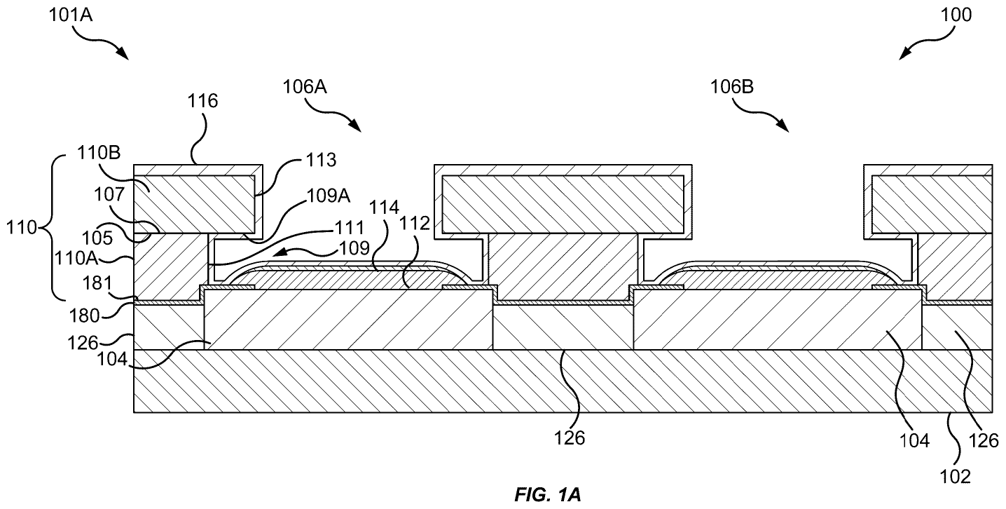

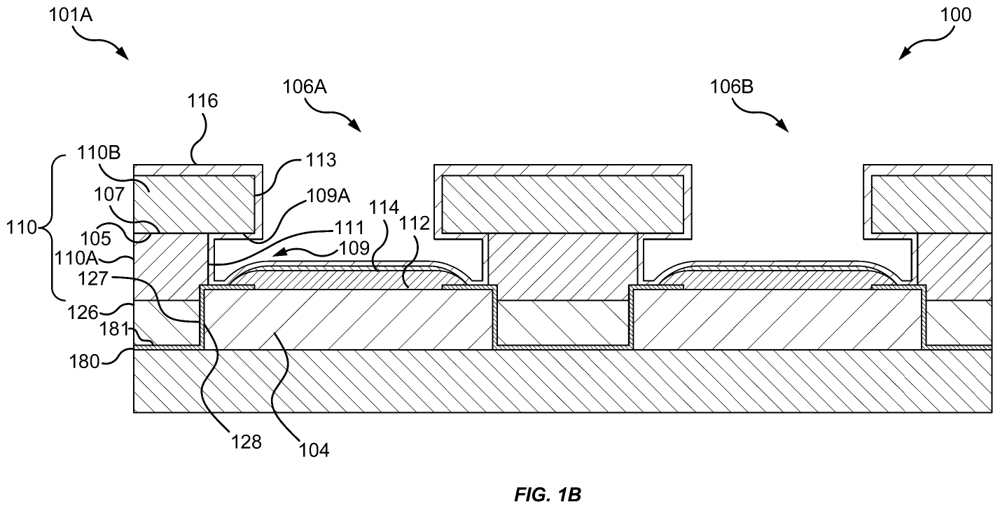

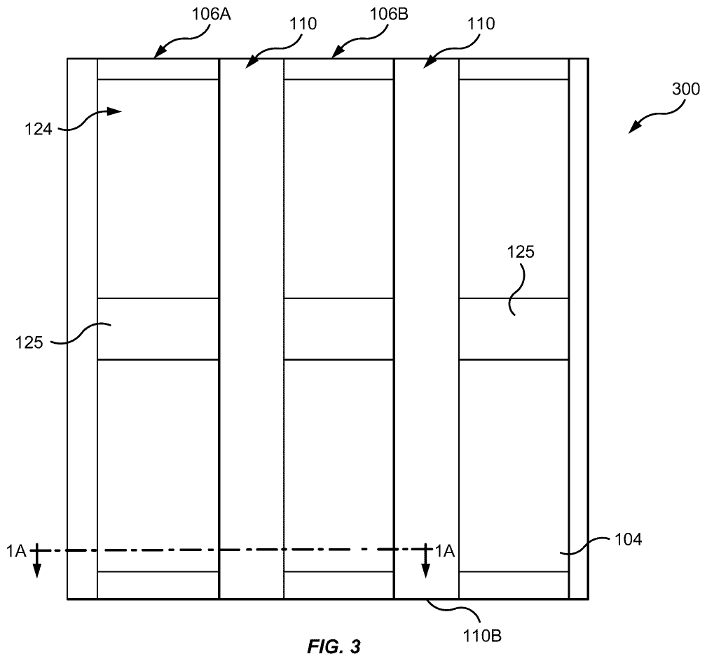

FIG. 1A is a schematic, cross-sectional view of a sub-pixel circuit 100 with a first protection layer configuration 101A according to one or more embodiments. The cross-sectional view of FIG. 1A is taken along section line 1A-1A of FIG. 3 (e.g., a pixel plane). FIG. 1B is a schematic, cross-sectional view of a sub-pixel circuit 100 with a second protection layer configuration 101B according to one or more embodiments. The cross-sectional view of FIG. 1B is taken along section line 1A-1A of FIG. 3 (e.g., a pixel plane). The sub-pixel circuit 100 includes a substrate 102. In one or more embodiments, the anodes 104 are pre-patterned on the substrate 102. E.g., the substrate is pre-patterned with anodes 104 of indium tin oxide (ITO). The anodes 104 are configured to operate as anodes of respective sub-pixels. In one embodiment, the anode 104 is a layer stack of a first transparent conductive oxide (TCO) layer, a second metal-containing layer disposed on the first TCO layer, and a third TCO layer disposed on the second metal-containing layer. The anodes 104 include, but are not limited to, chromium, titanium, gold, silver, copper, aluminum, ITO, a combination thereof, or other suitably conductive materials.

One or more PIS 126 are disposed over the substrate 102. The PIS 126 includes one of an organic material, an organic material with an inorganic coating disposed thereover, or an inorganic material. The organic material of the PIS 126 includes, but is not limited to, polyimides. The inorganic material of the PIS 126 includes, but is not limited to, silicon oxide (SiO₂), silicon nitride (Si₃N₄), silicon oxynitride (Si₂N₂O), magnesium fluoride (MgF₂), or combinations thereof.

The sub-pixel circuit 100 has a plurality of sub-pixel lines (e.g., first sub-pixel line 106A and second sub-pixel line 106B). The sub-pixel lines are adjacent to each other along the pixel plane. While FIG. 1A depicts the first sub-pixel line 106A and the second sub-pixel line 106B, the sub-pixel circuit 100 of the embodiments described herein may include two or more sub-pixel lines, such as a third sub-pixel line and a fourth sub-pixel. Each sub-pixel line has OLED materials configured to emit a white, red, green, blue or other color light when energized. In one or more embodiments the OLED materials within a pixel line are configured to emit the same color light when energized. In one or more embodiments the OLED materials within a pixel line are configured to emit different colors of light when energized

Each sub-pixel line includes overhang structures 110, with adjacent sub-pixel lines sharing the overhang structures 110 in the pixel plane. The overhang structures 110 are permanent to the sub-pixel circuit 100. The overhang structures 110 further define each sub-pixel line of the sub-pixel circuit 100. Each overhang structure 110 includes adjacent overhangs 109. The adjacent overhangs 109 are defined by an overhang extension 109A of a second structure 110B extending laterally past an upper surface 105 of a first structure 110A. In one or more embodiments the first structure 110A is disposed over the upper surface 181 of an inorganic layer 180.

The inorganic layer 180 is partly disposed over the PIS 126 and extends over part of the anode 104 under the overhang extension 109A such that the extension width the edge of the overhang extension 109A a sidewall 111 of the first structure 110A is substantially equal to the extension width of the inorganic layer 180 disposed over the anode 104. The inorganic layer has a thickness of about 15 nm or less. The second structure 110B is disposed over the first structure 110A. The second structure 110B may be disposed on the upper surface 105 of the first structure 110A.

In one embodiment, the overhang structures 110 include the second structure 110B of a conductive inorganic material and the first structure 110A of a non-conductive inorganic material. The conductive materials of the second structure 110B include a copper (Cu), aluminum (AI), aluminum neodymium (AlNd), molybdenum (Mo), molybdenum tungsten (MoW), or combinations thereof. The non-conductive materials of the first structure 110A include amorphous silicon (a-Si), titanium (Ti), silicon nitride (Si₃N₄), silicon oxide (SiO₂), silicon oxynitride (Si₂N₂O), or combinations thereof. The overhang structures 110 are able to remain in place, i.e., are permanent.

The adjacent overhangs 109 are defined by the overhang extension 109A. At least a bottom surface 107 of the second structure 110B is wider than the upper surface 105 of the first structure 110A to form the overhang extension 109A. The overhang extension 109A of the second structure 110B forms the overhang 109 and allows for the second structure 110B to shadow the first structure 110A. The shadowing of the overhang extension 109A provides for evaporation deposition of the inorganic layer 180, an OLED material 112, and a cathode 114. The inorganic layer 180 material may include a metal oxide containing-material, a silicon containing-material, or combinations thereof. The metal oxide containing-material includes, but is not limited to, aluminum oxide (Al₂O₃). The silicon containing material includes but is not limited to oxides, nitrides, or oxynitrides of silicon. The oxides, nitrides, or oxynitrides of silicon include, but are not limited to silicon oxide (SiO₂), silicon nitride (SiNₓ), silicon oxynitride (SiON), or combinations thereof. The OLED material 112 may include one or more of a HIL, a HTL, an EML, and an ETL. The OLED material 112 is partly disposed over and in contact with the anode 104. The OLED material 112 disposed under the overhang extension 109A is in contact with the upper surface 181 of the inorganic layer 180. The OLED material 112 is disposed under adjacent overhangs 109 and may contact a sidewall 111 of the first structure 110A. In one embodiment, the OLED material 112 is different from the material of the first structure 110A and the second structure 110B. The cathode 114 is disposed over the OLED material 112 and extends under the adjacent overhangs 109. The cathode 114 may extend past an endpoint of the OLED material 112. The cathode 114 may contact the upper surface 181 of the inorganic layer 180. The overhang structures 110 and an evaporation angle set by an evaporation source define deposition angles, i.e., the overhang structures provide for a shadowing effect during evaporation deposition with the evaporation angle set by the evaporation source.

The cathode 114 includes a conductive material, such as a metal. E.g., the cathode 114 includes, but is not limited to, silver, magnesium, chromium, titanium, aluminum, ITO, or a combination thereof. In one embodiment, material of the cathode 114 is different from the material of the first structure 110A and the second structure 110B. In one or more embodiments the OLED material 112 and the cathode 114 do not contact the sidewall 111 of the first structure 110A. In one or more embodiments the OLED material 112 contacts the sidewall 111 of the first structure 110A.

Each sub-pixel 106A, 106B includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhang extension 109A and along a sidewall 111 of each of the first structure 110A and the second structure 110B. The encapsulation layer 116 is disposed over the cathode 114 and extends past the cathode 114, between the cathode and the sidewall 111, and at least partially over the sidewall 111. In some embodiments, the encapsulation layer 116 extends to contact the sidewall 111 of the first structure 110A. In the illustrated embodiments as shown in FIGS. 1A and 1B, the encapsulation layer 116 extends to contact the second structure 110B at an underside surface of the overhang extension 109A, the sidewall 113 of the second structure 110B, and the upper surface of the second structure 110B. In some embodiments, the encapsulation layer 116 extends to contact the second structure 110B at an underside surface of the overhang extension 109A and to be disposed over the inorganic layer 180, the OLED material 112, and the cathode 114. In some embodiments, the encapsulation layer 116 ends at the sidewall 111 of the first structure 110A, i.e., is not disposed over the sidewall 113 of the second structure 110B, the upper surface of the second structure 110B, or the underside surface of the overhang extension 109A of the overhang structures 110. The encapsulation layer 116 includes the non-conductive inorganic material, such as the silicon-containing material. The silicon-containing material may include Si₃N₄ containing materials.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the sub-pixel circuit 100 further includes at least a global passivation layer disposed over the overhang structure 110 and the encapsulation layer 116. In yet another embodiment, the sub-pixel includes an intermediate passivation layer disposed over the overhang structures 110 of each of the sub-pixels 106A, 106B, and disposed between the encapsulation layer 116 and the global passivation layer.

FIG. 1B is a schematic, cross sectional view of sub-pixel circuit 100 according to one or more embodiments. Sub-pixel circuit 100 with a second protection layer configuration 101B includes an inorganic layer 180 disposed under a PIS 126. The PIS 126 is disposed over an upper surface 181 of the inorganic layer 180. The inorganic layer 180 extends between a sidewall 127 of the PIS and a sidewall 128 of the anode 104. The inorganic layer 180 extends over part of the anode 104 under the overhang extension 109A such that the width the edge of the overhang extension 109A a sidewall 111 of the first structure 110A is substantially equal to the width of the inorganic layer 180 disposed over the anode 104. The inorganic layer has a thickness of about 15 nm or less.

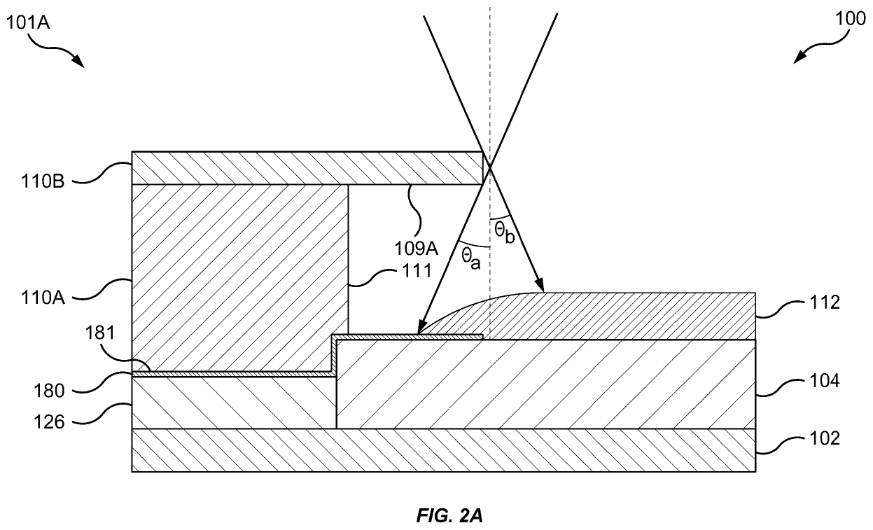

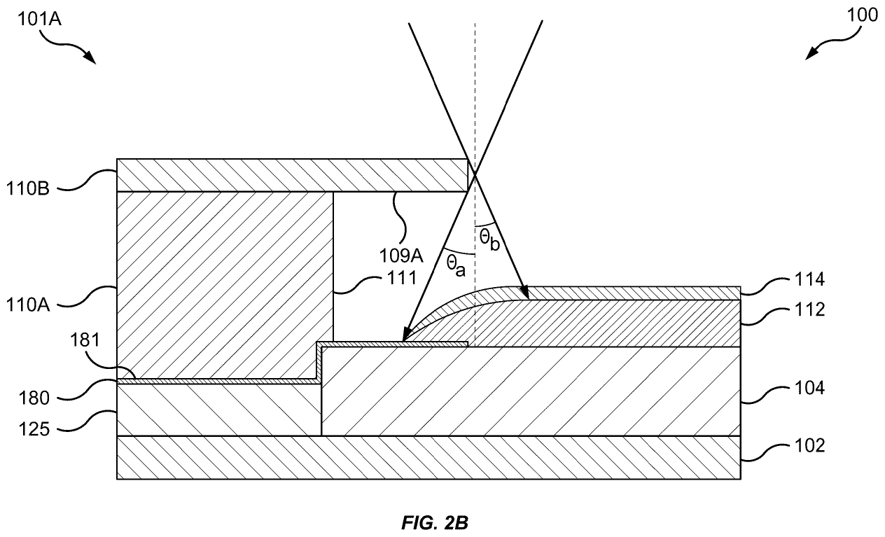

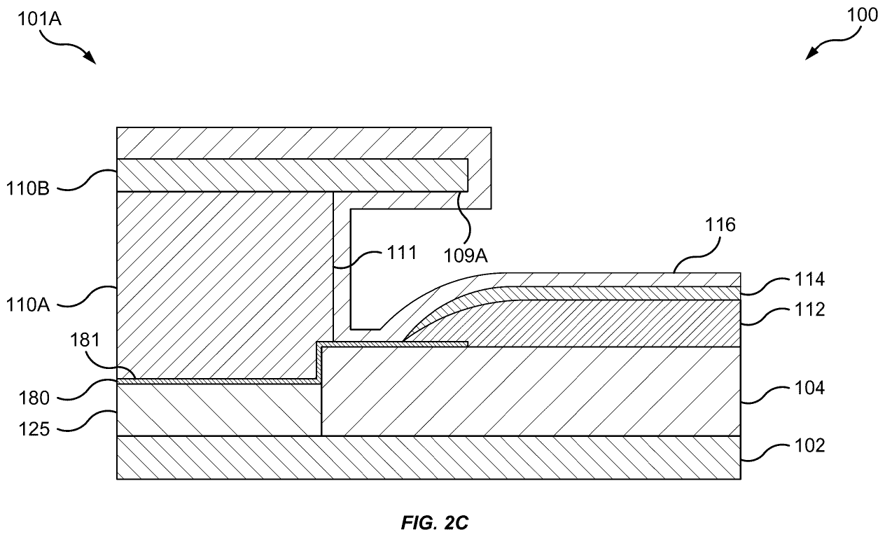

FIGS. 2A-2C are schematic, cross-sectional view of an overhang structure 110 of a sub-pixel circuit 100 with the first protection layer configuration 101A as shown in FIG. 1A according to one or more embodiments. In FIG. 2A, the inorganic layer 180 is disposed over the PIS 126. The first structure 110A is disposed over the upper surface 181 of the inorganic layer 180. The inorganic layer 180 extends between the first structure 110A and the anode 104. The inorganic layer 180 extends over part of the anode 104 under the overhang extension 109A such that the width the edge of the overhang extension 109A a sidewall 111 of the first structure 110A is substantially equal to the width of the inorganic layer 180 disposed over the anode 104. The OLED material 112 is disposed over the anode 104 and the inorganic layer 180 at two different angles ^{θ}a and ^{θ}b. Angles ^{θ}a and ^{θ}b are about equal to each other in opposite directions such that deposition profile of the OLED material 112 is the same for the overhang structures 110 defining the sub-pixel. The OLED material 112 is deposited at an angle relative to the overhang structures 110, such that the OLED material 112 deposited under the overhang extension 109A has a lesser thickness than the OLED material 112 not under the overhang extension 109A. The thickness of the OLED material 112 under the overhang extension 109A decreased as it approaches the sidewall 111. In one or more embodiments the OLED material 112 is deposited at an angle so that the OLED material 112 does not contact the sidewall 111. The OLED material 112 is at least partially disposed over the inorganic layer 180 under the overhang extension 109A. In one or more embodiments the OLED material 112 is deposited at an angle so that it contacts the sidewall 111.

In FIG. 2B, a cathode 114 is disposed over the OLED material 112 and the inorganic layer 180 at two different angles ^{θ}a and ^{θ}b. Angles ^{θ}a and ^{θ}b are about equal to each other in opposite directions such that deposition profile of the cathode 114 is the same for the overhang structures 110 defining the sub-pixel. The cathode 114 is deposited at an angle relative to the overhang structures 110, such that the cathode 114 deposited under the overhang extension 109A has a lesser thickness than the cathode 114 not under the overhang extension 109A. The thickness of the cathode 114 under the overhang extension 109A decreased as it approaches the sidewall 111. In one or more embodiments the cathode 114 is deposited at an angle so that the cathode 114 does not contact the sidewall 111. In one or more embodiments the cathode 114 extends past the OLED material 112 so that it comes into direct contact with the inorganic layer 180. The inorganic layer 180 protects against electrical leakage between the anode 104 and the cathode 114 deposited under the overhang extension 109A where the OLED material 112 may be too thin to prevent electrical leakage.

In FIG. 2C the encapsulation layer 116 is deposited over the cathode 114, the OLED material 112, and the inorganic layer 180. In one or more embodiments the encapsulation layer 116 extends along the sidewall 111, across the bottom surface of the overhang extension 109A and over the second structure 110B. In one or more embodiments the encapsulation layer 116 extends across a gap between the cathode 114 and the sidewall 111 and the encapsulation layer 116 directly contacts the upper surface 181 of the inorganic layer 180.

FIG. 3 is a schematic, top view of sub-pixel circuit 100 which either the first protection layer configuration 101A or the second protection layer configuration 101B, having a line-type architecture 300 according to embodiments. The line-type architecture 300 includes a plurality of pixel openings 124. Each of pixel opening 124 is abutted by overhang structures 110 and a separation structure 125 which define each of the sub-pixel line and sub-pixel of the line-type architecture 300.

Each sub-pixel line includes separation structures 125, with adjacent sub-pixels sharing the separation structures 125. The separation structures 125 are permanent to the sub-pixel circuit 100. The separation structures 125 further define each sub-pixel of the sub-pixel line of the sub-pixel circuit 100.

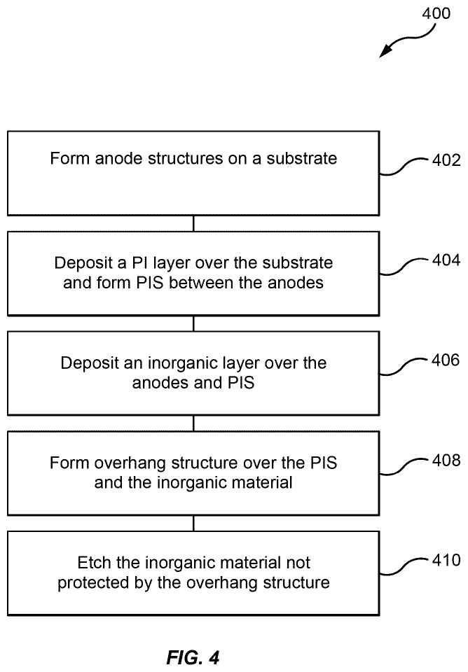

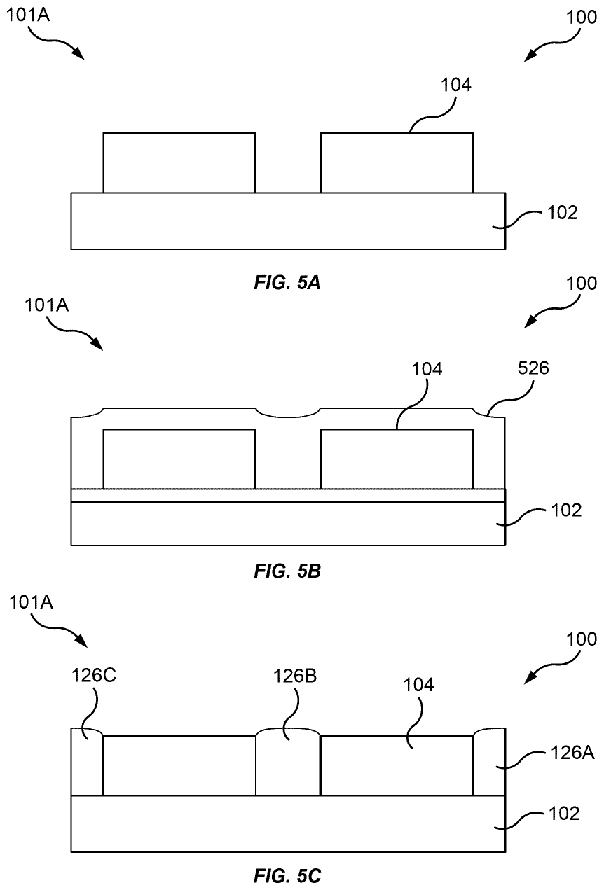

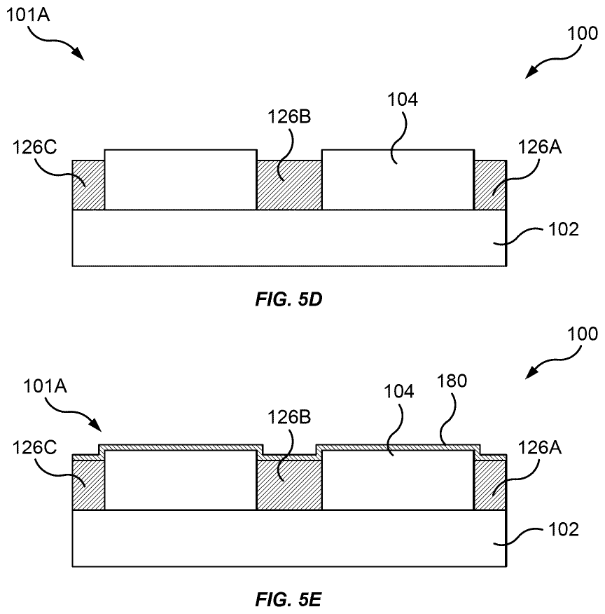

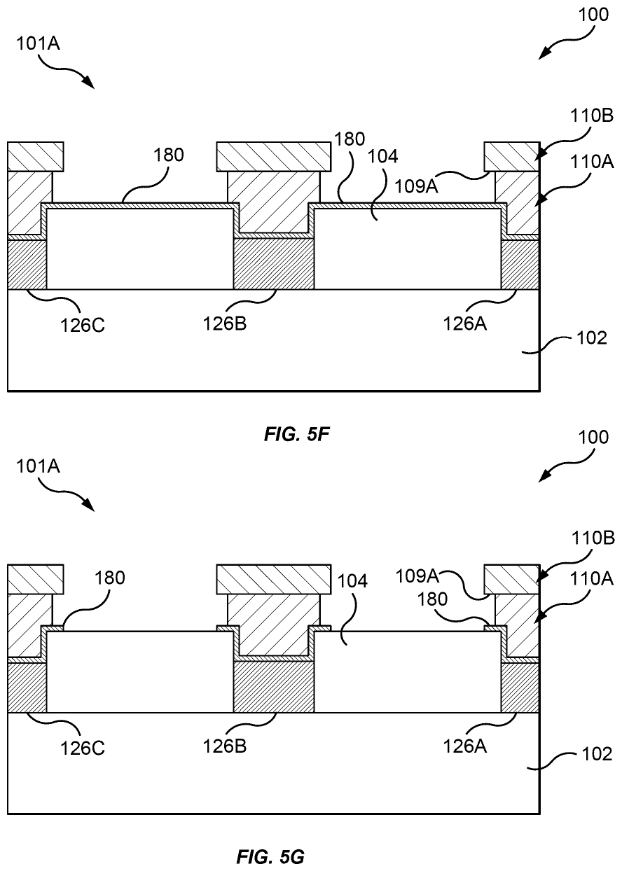

FIG. 4 is a flow diagram of a method 400 for forming a sub-pixel circuit 100 with the first protection layer configuration 101A according to one or more embodiments. FIG. 5A-5G are schematic, cross-sectional views of a substrate 102 during the method 400 for forming a sub-pixel circuit 100 with the first protection layer configuration 101A according to one or more embodiments.

At operation 402, as shown in FIG. 5A, anodes 104 are formed over a substrate. This can be done by depositing a layer of anode layer over the substrate 102, and then depositing a photoresist pattern over the anode layer. The anode layer not protected by the photoresist pattern is then etched away forming the desired anodes 104.

At operation 404, as shown in FIGS. 5B-5D, a pixel isolation (PI) layer 526 is deposited over the anodes 104 and the substrate 102. The PI layer 526 as show in in FIG. 5B is deposited over the anodes 104 and the substrate 102. The PI layer 526 is then etched away to form a first PIS 126A, a second PIS 126B and a third PIS 126C in between the anodes 104 as shown in FIG. 5C. The PIS 126A, 126B, 126C are then planarized such that that a top surface of each PIS 126A, 126B, 126C is aligned with one another and is below an upper surface of the anodes 104 as shown in FIG. 5D.

At operation 406, as shown in FIG. 5E, an inorganic layer 180 is deposited over the anodes 104 and the PIS 126A, 126B, 126C. In one or more embodiments the inorganic layer 180 is deposited using evaporation deposition. In one or more embodiments the inorganic layer 180 is made of a dielectric material such as aluminum oxide (Al₂O₃).

At operation 408 as shown in FIG. 5F, overhang structures 110 are formed over each PIS 126A, 126B, 126C on top of the inorganic layer 180. The overhang structures 110 can be formed by depositing a first overhang layer and a second overhang layer, and etching away the desired areas using a photoresist in order to form the overhang structures.

At operation 410 as shown in FIG. 5G, the exposed areas of the inorganic layer 180 not protected by the overhang extensions 109A are etched away so that the portions of the inorganic layer 180 that are positioned under the overhang extensions 109A of the overhang structures 110 remain. The portion of the inorganic layer 180 that extends over the anode 104 has a width that is about equivalent to the width of the overhang extension 109A.

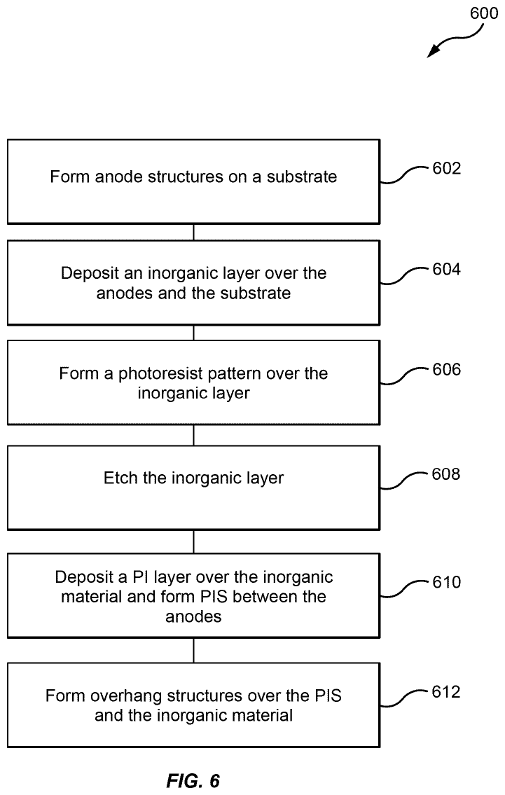

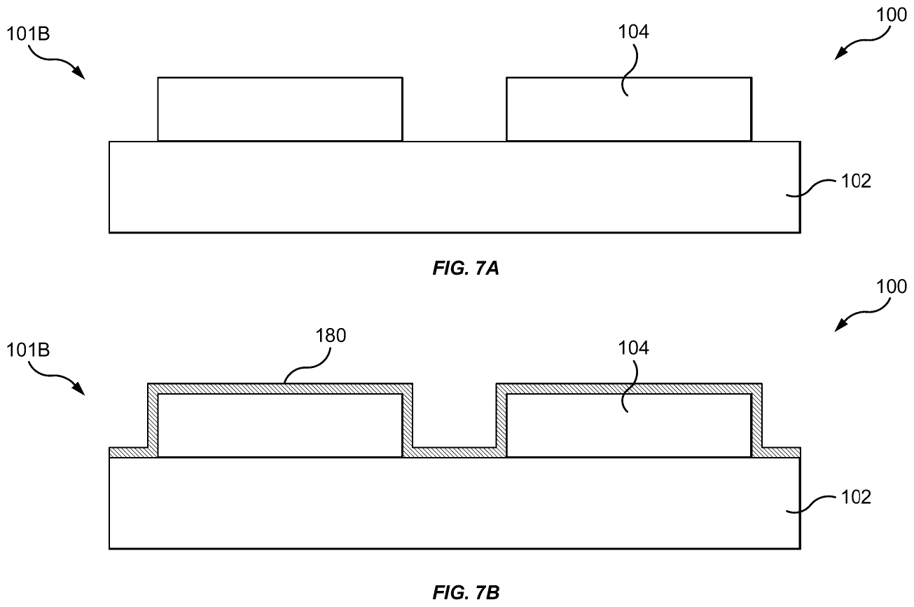

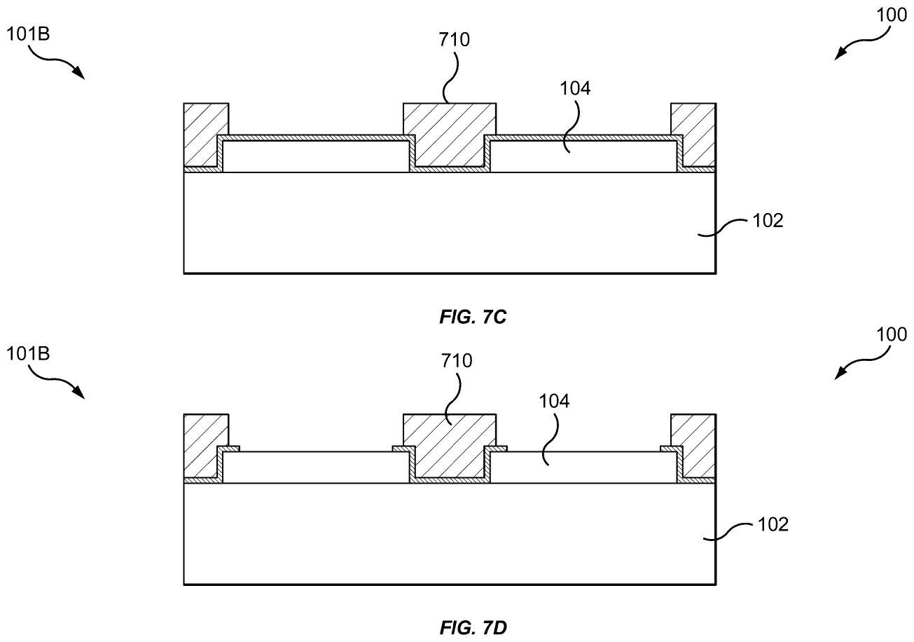

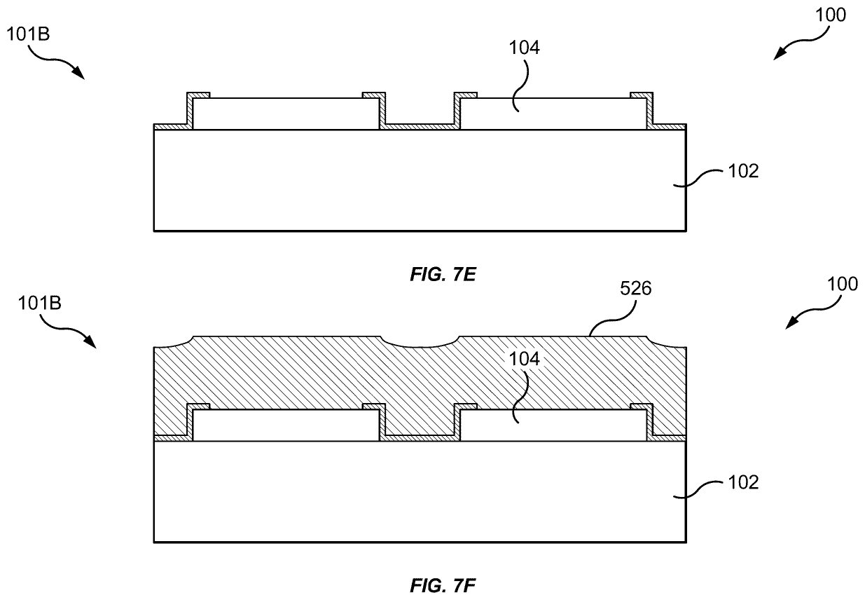

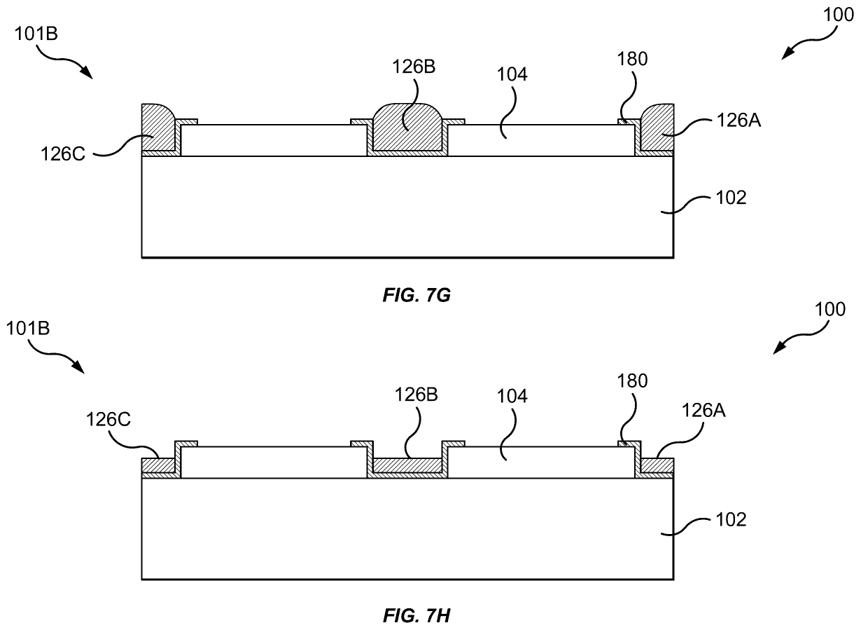

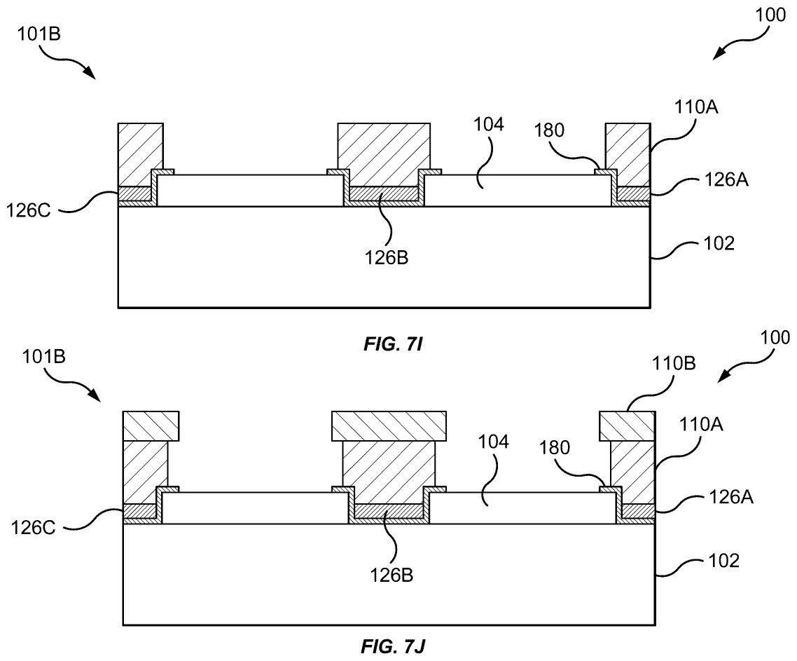

FIG. 6 is a flow diagram of a method 600 for forming a sub-pixel circuit 100 with the second protection layer configuration 101B as shown in FIG. 1B according to one or more embodiments. FIGS. 7A-7J are schematic, cross-sectional views of a substrate 102 during the method 600 for forming a sub-pixel circuit 100 with the second protection layer configuration 101B according to one or more embodiments.

At operation 602 as shown in FIG. 7A, anodes 104 are formed over a substrate 102. This can be done by depositing a layer of anode layer over the substrate 102, and then depositing a photoresist pattern over the anode layer. The anode layer not protected by the photoresist pattern is then etched away forming the desired anodes 104.

At operation 604 as shown in FIG. 7B, an inorganic layer 180 is deposited over the substrate 102 and the anodes 104. In one or more embodiments the inorganic layer 180 is deposited using evaporation deposition. In one or more embodiments the inorganic layer 180 is made of a dielectric material such as aluminum oxide (Al₂O₃).

At operation 606 as shown in FIG. 7C, a photoresist pattern 710 is deposited over the inorganic layer 180. Either a positive photoresist or a negative photoresist can be used in this operation.

At operation 608 as shown in FIGS. 7D-7E, the inorganic layer 180, not protected by the photoresist pattern 710 is etched away. The photoresist pattern 710 extends over the anode 104 so that a portion of the inorganic layer 180 extends over the top of the anode 104. The width of the inorganic layer 180 disposed on the anode 104 is about equivalent to the width of the overhang extension 109A of the overhang structure 110 to be disposed over the inorganic layer 180. The photoresist pattern 710 is then removed as shown in FIG. 7E.

At operation 610, as shown in FIGS. 7F-7H a pixel isolation (PI) layer 526 is deposited over the anodes 104 and the inorganic layer 180. The PI layer 526 as shown in in FIG. 7F is deposited over the anodes 104 and the substrate 102. The PI layer 526 is then etched away to form a first PIS 126A, a second PIS 126B and a third PIS 126C in between the anodes 104 on top of the inorganic layer 180 as shown in FIG. 7G. The PIS 126A, 126B, 126C are then planarized such that a top surface of each PIS 126A, 126B, 126C is aligned with one another and is below an upper surface of the anodes 104 as shown in FIG. 7H. In one or more embodiments, operation 610 is performed prior to operation 602. In one or more embodiments, operation 602 is performed prior to operation 610.

At operation 612, as shown in FIGS. 71-7J overhang structures 110 are formed over each PIS 126A, 126B, 126C on top of the inorganic layer 180. The overhang structures 110 can be formed by depositing a first overhang layer and a second overhang layer, and etching away the desired areas using a photo resist in order to form the overhang structures. In one or more embodiments, operation 612 is performed prior to operation 602. In one or more embodiments, operation 602 is performed prior to operation 612.

In summation, a device is disclosed. The device includes a plurality of sub-pixels. The sub-pixels each include an anode, an inorganic layer, overhang structures, separation structures, an organic light emitting diode (OLED) material, and a cathode. The anode is defined by adjacent overhang structures. The overhang structures are disposed over an inorganic layer. The overhang structures include a second structure disposed over the first structure. A bottom surface of the second structure extends laterally past an upper surface of the first structure. The OLED material is disposed over the anode and the inorganic layer. The cathode is disposed over the OLED material and the inorganic layer.

Benefits of the present disclosure include decreased electrical leakage between the anode and the cathode and enhanced device performance.

It is contemplated that one or more aspects disclosed herein may be combined. As an example, one or more aspects, features, components, operations, and/or properties of the various implementations of the sub-pixel circuit 100, the first protection layer configuration 101A, the second protection layer configuration 101B, the inorganic layer 180, the anode 104, the PIS 126, the overhang structures 110, the OLED material 112, the cathode 114, the encapsulation layer 116, the method 400 and/or the method 600 may be combined. Moreover, it is contemplated that one or more aspects disclosed herein may include some or all of the aforementioned benefits

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
a substrate;
overhang structures, the overhang structures including an extension disposed past a sidewall of the overhang structures;
an anode disposed over the substrate;
an inorganic layer disposed under each extension of the overhang structures;
organic light-emitting diode (OLED) material disposed over the anode, wherein the OLED material is disposed between the inorganic layer under each extension of the overhang structures; and
a cathode disposed over the OLED material.

2. The sub-pixel of claim 1, further comprising isolation structures disposed over the substrate, adjacent isolation structures having the anode therebetween.

3. The sub-pixel of claim 1, wherein an extension width from an edge of the extension to the sidewall is substantially equal to a width of the inorganic layer from the edge of the inorganic layer to the sidewall of each overhang structure.

4. The sub-pixel of claim 2, wherein the inorganic layer is disposed above the the isolation structures.

5. The sub-pixel of claim 2, wherein the inorganic layer is disposed below the isolation structures.

6. The sub-pixel of claim 1, wherein the inorganic layer comprises a dielectric material.

7. The sub-pixel of claim 1, wherein the inorganic layer comprises a metal oxide containing-material, a silicon containing material, or combinations thereof.

8. The sub-pixel of claim 1, wherein the inorganic layer has a thickness of 15 nm or less.

9. The sub-pixel of claim 1, further comprising:
an encapsulation layer disposed over the cathode and past an endpoint of the cathode, wherein the encapsulation layer extends under at least a portion of the extensions of overhang structures, along the sidewall of the overhang structures, and contacts a bottom surface of the extensions of the overhang structures.

10. The sub-pixel of claim 1, wherein the OLED material is disposed over at least a portion of the inorganic layer.

11. A sub-pixel, the sub-pixel comprising overhang structures disposed over a substrate including an extension disposed past a sidewall of the overhang structures, an anode disposed over the substrate, an inorganic layer disposed under each extension of the overhang structures, wherein the sub-pixel is made by a process comprising:
depositing an organic light-emitting diode (OLED) material over the substrate, the OLED is disposed over the anode, wherein the inorganic layer under each extension of the overhang structures is disposed between the OLED material; and
depositing a cathode, wherein the cathode is disposed under each extension of the overhang structures.

12. The sub-pixel of claim 11, wherein the inorganic layer is deposited using evaporation deposition.

13. The sub-pixel of claim 11, wherein the OLED material is deposited at an angle relative to the substrate.

14. The sub-pixel of claim 11, further comprising isolation structures disposed over the substrate, adjacent isolation structures having the anode therebetween.

15. A method, comprising:
depositing an inorganic layer over a substrate;
removing portions of the inorganic layer, such that the inorganic layer is to be disposed under an extension of overhang structures;
forming the overhang structures, the overhang structures including the extension disposed past a sidewall of the overhang structures;
depositing an organic light-emitting diode (OLED) material over the substrate, the OLED is disposed over an anode, wherein the inorganic layer under each extension of the overhang structures is disposed between the OLED material; and
depositing a cathode, wherein the cathode is disposed under each extension of the overhang structures.

16. The method of claim 15, further comprising:
depositing a pixel isolation layer over the substrate; and
removing portions of the pixel isolation layer, such that pixel isolation structures are to be disposed under a first portion of the overhang structure.

17. The method of claim 16, wherein the inorganic layer is deposited prior to the pixel isolation layer.

18. The method of claim 16, wherein the pixel isolation layer is deposited prior to the inorganic layer.

19. The method of claim 16, wherein the portions of the inorganic layer are removed prior to forming the overhang structures.

20. The method of claim 16, wherein the portions of the inorganic layer are removed after forming the overhang structures.
